(19) United States
(12) Patent Application Publication
(10) Pub. No.: US 2012/0222726 A1
(43) Pub. Date: Sep. 6, 2012

(54) THIN FILM SOLAR CELL MODULE

(75) Inventors: Huaili Qin, Shanghai (CN); Stan Shi, Shanghai (CN); Michael Ren, Shanghai (CN)

(73) Assignee: E.I. DU PONT DE NEMOURS AND COMPANY, Wilmington, DE (US)

(21) Appl. No.: 13/225,785

(22) Filed: Sep. 6, 2011

(30) Foreign Application Priority Data
Sep. 7, 2010 (CN) 201010276508.6

(51) Int. Cl. H01L 31/05; H01L 31/048

(52) U.S. Cl. 136/251; 136/244

(57) ABSTRACT

A thin film solar cell module comprises a solar cell panel with a layer of solar cells, two bus bars extending along edges of the solar cell panel, and a junction box with a connecting circuit that extends along an edge of the solar cell panel. A bypass diode in the junction box connecting circuit prevents circuit breaking or reverse current from occurring in the cell panel. The two bus bars are connected to the junction box connecting circuit at opposite ends of the solar panel edge and on at opposite sides of the bypass diode. The thin film solar cell module has an improved appearance, is easy to assemble and maintain, and reduces the need for fastening and protection of cables.

### TECHNICAL FIELD

The present application relates to a thin film solar cell module comprising a junction box disposed along a transversely extended edge of the cell panel.

### BACKGROUND ART

Recently, thin film solar cells become an area of high interest in the development of the field of solar cells (photovoltaic cells) due to their low use of silicon, low cost and high efficiency. Thin film solar cells are mainly categorized into the following types: non-crystalline silicon based thin film solar cells, microcrystalline silicon based thin film solar cells, dye-sensitized thin film solar cells, organic thin film solar cells, copper-indium-selenide thin film solar cells, copper-indium-gallium-selenide thin film solar cells, cadmium telluride thin film solar cells, etc.

FIG. 1 shows a common thin film solar cell module, which is mainly comprised of cell panel 10, frame 30 surrounding the periphery of the cell panel and junction box 50 for outputting the electrical energy generated by the cell panel.

Two main structures of cell panel 10 (not shown) are described below.

Depending on the selection of materials and mode of preparation of the thin film cell module, in the state of practical use, the cell panel 10 has a front side facing the sunlight and a back side opposite the sunlight.

A first kind of cell panel 10 may mainly include (in the direction from back side to front side): a cell substrate, a layer of cells attached to the surface of the front side of the cell substrate, bus bars positioned on the surface of the front side of the layer of cells, a (front) encapsulation layer covering the front side of the layer of cells and the bus bars, and a front panel covering the front side of the (front) encapsulation layer. If the substrate is very thin or has insufficient rigidity itself, there can be added a (back) encapsulation layer covering the back side of the substrate and a back panel covering the back side of the (back) encapsulation layer.

A second kind of cell panel 10 may mainly include (in the direction from front side to back side): a cell superstrate, a layer of cells attached to the surface of the back side of the cell superstrate, bus bars positioned on the surface of the back side of the layer of cells, a (back) encapsulation layer covering the back side of the layer of cells and the bus bars, and a back panel covering the back side of the (back) encapsulation layer.

The layer of cells is divided into a plurality of cells which extend in a longitudinal direction.

The electrical current generated by these cells is gathered to junction box 50 via said bus bars. In particular, on the surface of the front side or the back side of the layer of cells, two longitudinal main bus bars 12 are disposed along the left and right edges of the layer of cells, and two transverse bus bars 12 respectively extend transversely from the two longitudinal main bus bars to junction box 50 and connect with the junction box.

Frame 30 is assembled from aluminum alloy extruded section bar segments 32 (and possible corner joints 34 that are inserted into the hollow portion of section bar segments 32).

Frame 30 can be made of composite materials, high strength plastics, or can be made of metals such as aluminum alloy. The materials for the corner joints can be the same as or different from those for the frame segments.

Generally, junction box 50 is attached to the back side of the back panel of cell panel 10. Junction box 50 has positive and negative terminals and a connecting circuit disposed between the terminals. Bypass diode 52 is disposed in series in the connecting circuit for preventing circuit breaking or reverse current from occurring in the solar cell module.

Outputting cables 54 of the thin film solar cell module are connected to the positive and negative terminals. Cell panel 10 of the thin film solar cell module is respectively connected to the opposite ends of the diode.

During the assembling of such a conventional thin film solar cell module, the back panel of the module needs to be cut at a position corresponding to the junction box to form an opening, and then the transverse bus bars 12 are passed through the opening in the back panel, drawn from cell panel 10 and connected to junction box 50. Afterwards, the edges of cell panel 10 are coated with sealing glue and then inserted and fastened in frame 30.

The assembling process of the above thin film solar cell module is very complicated. The disposing of bus bars in the module entails an insulation operation, and the drawing of the bus bars out of the back panel entails cutting or boring the back panel. As the thin film cell is very sensitive to moisture, the cut or bore in the back panel readily allows moisture to diffuse in, thus reducing the reliability of the whole cell module and affecting the service lifetime of the cell module.

Moreover, the efficiency of electricity generation of the solar cell module decreases with increased temperature. The junction box reaches a high temperature when at work, and the attachment of the junction box to the back side of the cell module affects the heat dissipation at the attachment site. This will result in localized temperature rise in the cell module, thus affecting the overall efficiency of the cell module and reducing the service lifetime of the assembly.

Additionally, outputting cables drawn from the junction box at the back side of the cell module must be used in order to connect the plurality of cells in series and/or in parallel to form the solar cell system. Such mode of connection is rather troublesome and time-consuming. Also, the use of cables for connection and the protection and fastening of the cables will increase the cost of the solar cell system.

Further, because the back side of the cell module is visible, the presence of the junction box and outputting cables at the back side of the cell module makes the back side cluttered and not aesthetically pleasing.

Therefore, there is a desire for an improved thin film solar cell module to address the above-issues with conventional thin film solar cell modules.

### SUMMARY OF THE INVENTION

The present application is intended to provide an improved thin film solar cell module which obviates the problem of localized temperature rise of the assembly due to the junction box that will affect the outputting efficiency and reduce the long-term service lifetime of the assembly. Moreover, the thin film solar cell module is tidy and aesthetically pleasing, and is easy to assemble. Also, the junction boxes of a plurality of solar cell modules can achieve electrical connection in an easy and low-cost manner.

According to an aspect of the present application, there is provided a thin film solar cell module which comprises: a thin film solar cell panel comprising a layer of cells and the bus bars, the layer of cells including a plurality of cells which extend in a longitudinal direction and are connected in series with each other in a transverse direction, and the bus bars respectively extending along the two longitudinally extended edges of the solar cell panel for outputting electrical energy generated by the solar cells; and a junction box disposed along a transversely extended edge of the solar cell panel and comprising a box body and a connecting circuit for gathering and outputting electrical energy generated by the solar cell panel, the connecting circuit comprising a conductive wire extending along the whole length of said transversely extended edge and at least partly passing through the box body of the junction box, a bypass diode connected in the conductive wire within the box body of the junction box for preventing circuit breaking or reverse current from occurring in the cell panel, with the two bus bars connected to the conductive wire at the opposite sides of the diode respectively; and a male and a female connector connected to the conductive wire at the opposite sides of the diode respectively for providing external connections; wherein the two bus bars are directly connected to the opposite terminals of the conductive wire at the opposite ends of said transversely extended edge of the cell panel.

According to another preferred embodiment of the present application, the box body of the junction box forms a frame segment extending along said transversely extended edge of the cell panel and/or corner joints at both ends of the frame segment; the thin film solar cell module further comprises additional frame segments; and the frame segment extending along said transversely extended edge of the solar cell panel and the additional frame segments form a frame that at least partially surrounds the periphery of the solar cell panel.

According to another preferred embodiment of the present application, the frame segment and/or the corner joints formed by the box body of the junction box are made of an insulating material, such as a plastic or a composite material.

According to another preferred embodiment of the present application, the additional frame segments are made of a composite material or a metal, such as aluminum alloy.

According to another preferred embodiment of the present application, the additional frame segments are section bar segments cut from a section bar.

According to another preferred embodiment of the present application, a plug portion of the male connector and a socket portion of the female connector protrude from the frame segment extending along said transversely extended edge of the cell panel and/or the corner joints at both ends of the frame segment, and preferably, they are disposed within the inside of the additional frame segments and are removable from the inside of the additional frame segments or accessible from outside to facilitate connection operation on them.

According to another preferred embodiment of the present application, the additional frame segments comprise a body portion and a receiving portion formed integral with the body portion adapted for clamping an edge of the cell panel.

According to another preferred embodiment of the present application, the frame segment and/or the corner joints formed by the box body of the junction box each comprise a canister-shaped body portion and a receiving portion formed integral with the body portion adapted for clamping an edge of the solar cell panel; and the receiving portion of the frame segment and/or the corner joints formed by the box body of the junction box has an external shape identical with that of the receiving portion of the additional frame segments.

According to another preferred embodiment of the present application, the box body of the junction box comprises two box portions which are respectively disposed at the opposite ends of said transversely extended edge of the solar cell panel; the conductive wire comprises two substrates respectively disposed in the two box portions and an intermediate wire connected between the two substrates, with the diode being disposed on one of the substrates; the substrate with the diode is comprised of an inner and an outer conductive portion and an insulating portion positioned between and electrically isolating the inner and the outer conductive portion, with both ends of the diode being fastened to the two conductive portions respectively, and the other substrate without the diode is a conductive plate; one of the male and female connectors is connected to the conductive plate, and the other of the male and female connectors is connected to the outer conductive portion of the substrate with the diode.

According to another preferred embodiment of the present application, the two box portions form corner joints at the opposite ends of the same frame segment which extends along said transversely extended edge of the solar cell panel.

According to another preferred embodiment of the present application, the two box portions are assembled at the opposite ends of the same frame segment which extends along said transversely extended edge of the solar cell panel.

According to another preferred embodiment of the present application, the thin film solar cell module is frameless. In this case, the thin film solar cell panel is of the type that comprises a front and a back glass panel.

According to another preferred embodiment of the present application, the box body of the junction box further comprises an intermediate segment disposed between the two box portions, with the two box portions and the intermediate segment having identical external shape.

According to another preferred embodiment of the present application, the box body of the junction box further comprises an intermediate segment disposed between the two box portions, with the two box portions and the intermediate segment having identical external shape.

According to another preferred embodiment of the present application, the box body of the junction box is adhesively attached to said transversely extended edge of the solar cell panel.

According to another preferred embodiment of the present application, the two box portions and the intermediate segment of the box body of the junction box are each provided with a receiving portion for receiving an edge of the solar cell panel.

In the innovative thin film solar cell module according to the present application, the junction box is disposed at an edge of the cell panel instead of being assembled at the back side of the cell panel. Therefore, the junction box can be rapidly set up on the cell panel.

Moreover, there is no need to cut or bore in the back panel, and the junction box will not cause localized temperature rise in the cell module, so that the outputting efficiency of the assembly will not be affected and the long-term service lifetime of the assembly will not be reduced.

Additionally, the thin film solar cell modules according to the present application can achieve electrical connection among them simply through insertion and joining of the connectors, without the need to use any extra cables and to fasten and protect the cables. This allows that the assembling process of the thin film solar cell modules can be carried out in a simple, rapid and low-cost manner.

Further, no junction box and outputting cables are disposed on the back side of the thin film solar cell modules according to the present application, therefore the back side of the cell module is not cluttered and is aesthetically pleasing.

### BRIEF DESCRIPTION OF THE DRAWINGS

The preferred embodiments of the present application will be illustrated below with reference to the drawings, in which:

FIG. 1 is the schematic depiction of a thin film solar cell module according to the prior art.

FIG. 2 is the schematic depiction of a thin film solar cell module according to a preferred embodiment of the present application.

FIG. 3 is the schematic depiction of another thin film solar cell module according to a preferred embodiment of the present application.

FIG. 4-11 schematically show the various parts of the thin film solar cell module in FIG. 3 and their mode of assembling.

FIG. 12 is the schematic depiction of another thin film solar cell module according to a preferred embodiment of the present application.

FIG. 13-20 schematically show the various parts of the thin film solar cell module in FIG. 12 and their mode of assembling.

FIG. 21 is the schematic depiction of another thin film solar cell module according to a preferred embodiment of the present application.

FIG. 22-19 schematically show the various parts of the thin film solar cell module in FIG. 21 and their mode of assembling.

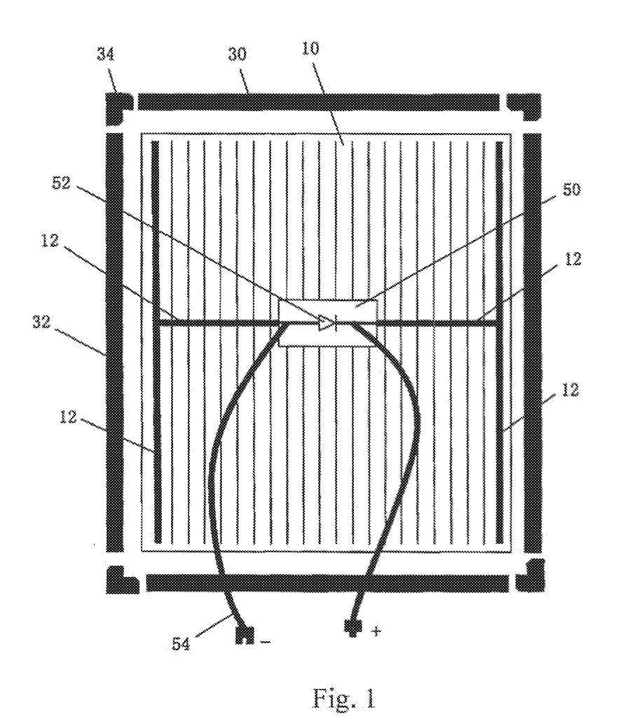

### DETAILED DESCRIPTION OF THE INVENTION

Various preferred embodiments of the present application will be described below with reference to the drawings.

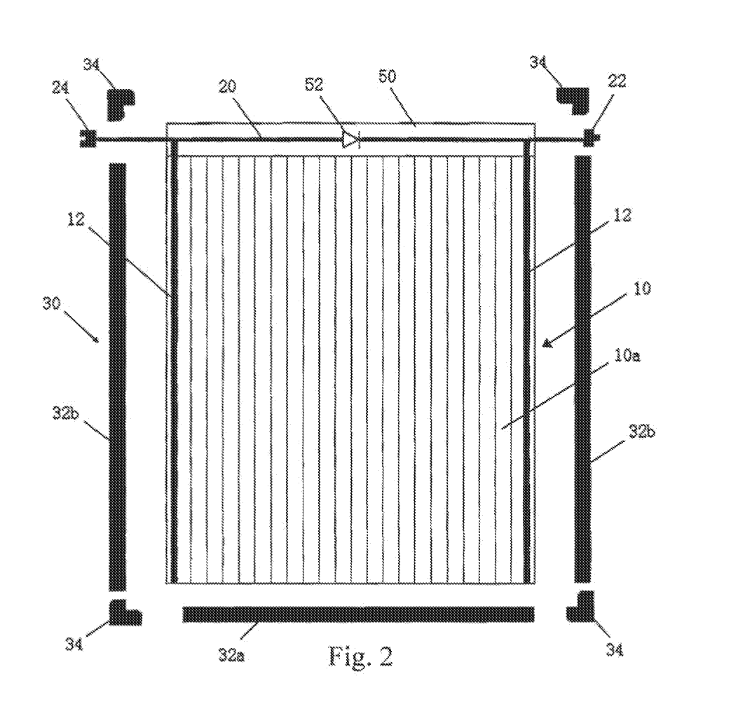

As shown in FIG. 2, according to a preferred embodiment of the present application, a thin film solar cell module mainly comprises cell panel 10, frame 30 and junction box 50.

In the illustrated embodiment, cell panel 10 is substantially rectangular, thereby defining the longitudinal direction and transverse direction of the cell panel.

In the state of practical use, the cell panel 10 has a front side for facing the sunlight and a back side for facing opposite the sunlight.

As an example (not shown), cell panel 10 of the thin film solar cell module according to the present disclosure mainly comprises (in the direction from back side to front side): a cell substrate (such as made of glass, polymer, metal, etc), a layer of cells attached to the front side of the cell substrate (non-crystalline silicon based, microcrystalline silicon based, dye-sensitized, organic type, copper-indium-selenide type, copper-indium-gallium-selenide type, cadmium telluride thin film, etc), bus bars positioned on the surface of the front side of the layer of cells, a (front) encapsulation layer covering the front side of the layer of cells and the bus bars, and a front panel covering the front side of the (front) encapsulation layer (such as made of glass or transparent polymer, etc). If said substrate is very thin or has insufficient rigidity itself (e.g., when the substrate is made of certain kinds of resins, its rigidity may be insufficient), there can be added a (back) encapsulation layer covering the back side of the substrate and a back panel covering the back side of the (back) encapsulation layer (such as made of glass, polymer, metal, etc).

As another example (not shown), cell panel 10 of the thin film solar cell module according to the present disclosure includes (in the direction from front side to back side): a cell superstrate (such as made of glass, polymer etc.), a layer of cells attached to the back side of the cell superstrate (non-crystalline silicon based, microcrystalline silicon based, dye-sensitized, organic type, copper-indium-selenide type, copper-indium-gallium-selenide type, cadmium telluride thin film, etc), bus bars positioned on the surface of the back side of the layer of cells, a (back) encapsulation layer covering the back side of the layer of cells and the bus bars, and a back panel covering the back side of the (back) encapsulation layer (such as made of glass, polymers, metals, etc).

The materials for the front panel and the superstrate must be light-transmissive materials, and can be, but not limited to, glass; polymers, such as polycarbonates, acrylates, polyacrylates, cyclic polyolefins, ethylene-norbornene copolymer, polystyrene, polyamide, polyester, fluoropolymers, or combinations thereof.

The materials for said back panel and said substrate can be, but not limited to, glass; polymers, such as polycarbonates, acrylates, polyacrylates, cyclic polyolefins, ethylene-norbornene copolymer, polystyrene, polyamide, polyester, fluoropolymers, or combinations thereof; metals, such as aluminum, steel, galvanized steel; or ceramics.

The layer of cells in the cell panel 10 is comprised of a plurality of cells 10a which extend in a longitudinal direction (in the direction parallel to the long sides of the rectangle of the cell panel, as shown in FIG. 2) and are connected in series with each other in a transverse direction. The electrical current generated by these cells 10a is gathered to a junction box 50 through bus bars 12 that respectively extend in a longitudinal direction along the left and right edges of the cell panel (the two long sides of the rectangle of the cell panel, as shown in FIG. 2).

According to this embodiment, junction box 50 extends along a transversely extended edge of cell panel 10 (a short side of the cell panel, as shown in FIG. 2) and singly forms the frame segment at that edge.

Frame 30 surrounds the periphery of cell panel 10 to protect the cell panel. In this embodiment, the frame is segmented (jointed by segments). However, the present disclosure also applies to integral frames as well as various other forms of frames.

The segmented frame 30 shown in FIG. 2 includes a transversely extended frame segment comprised of junction box 50 at one side, a transversely extended frame segment 32a at the other side opposite junction box 50, two longitudinally extended (along the two long sides of the cell panel) frame segments 32b opposite each other, and four corner joints 34 connecting these frame segments with each other to form the rectangular frame.

The individual frame segments 32a and 32b are preferably straight section bar segments, so that they can be cut from the same section bar, thus reducing manufacturing cost. The section bar is preferably formed by extrusion of metals such as aluminum alloy; alternatively, it can be formed by injection or extrusion of composite materials or high strength plastics. Suitable high strength plastics for use in practicing the invention comprise thermoplastic polyester homopolymers and copolymers. Thermoplastic polyesters are typically derived from one or more dicarboxylic acids and diols. Suitable thermoplastic polyesters include without limitation poly(ethylene terephthalate) (PET), poly(trimethylene terephthalate) (PTT), poly(1,4-butylene terephthalate) (PBT), poly(ethylene 2,6-naphthoate) (PEN), and poly(1,4-cyclohexyldimethylene terephthalate) (PCT) and copolymers and blends of the same. Of these, the preferred thermoplastic polyesters are selected from poly(ethylene terephthalate) (PET), poly(trimethylene terephthalate) (PTT), and poly(1,4-butylene terephthalate) (PBT). Examples of commercially available polyesters for use in the invention include Crastin® PBT polyester resins, Rynite® poly(ethylene terephthalate) polyester resins, and Sorona® polyester resins, all available from DuPont.

Seen from cross section, the individual frame segments 32a and 32b respectively have a receiving portion and a body portion formed integral with each other (as described hereinafter). The receiving portion is adapted for clamping and sealing the edges of the cell panel, and the body portion is used to provide structural strength and rigidity.

Junction box 50 includes a box body that extends along the transversely extended edge of the solar cell panel and a connecting circuit that at least partly passes through the box body and that is used for gathering and outputting electrical energy generated by the cell panel. The box body preferably has the same length as that of frame segments 32b, and preferably has identical cross section along its whole length. The box body has a receiving portion and a canister-shaped body portion, the receiving portion being adapted for clamping and sealing the edges of the cell panel, and the canister-shaped body portion being used for providing structural strength and rigidity and being used as the assembling space through which the connection circuit is passed (as described hereinafter).

As an optional embodiment, the individual frame segments 32a and 32b may have the same shape as that of junction box 50, that is, other frame segments may have the same receiving portion and canister-shaped body portion as those of the box body of the junction box.

As another optional embodiment, the individual frame segments 32a and 32b may have the same receiving portion as that of junction box 50, but the body portion of the individual frame segments 32a and 32b may be different from the canister-shaped body portion of the box body of the junction box. The body portion of the individual frame segments 32a and 32b can have various appropriate cross sections, such as an open type cross section.

Corner joints 34 have branches that extend perpendicularly with each other and that are used for assembling the adjacent frame segments together through insertion and joining. After the adjacent frame segments are assembled together, the corner joints between them can be exposed outside, or can be concealed by being completely inserted into the frame segments.

If the corner joints are exposed outside, a first of their branches can have a receiving portion and a body portion, the receiving portion being adapted for clamping and sealing the edges of the cell panel, and the body portion being used for providing structural strength and rigidity. The body portion can be solid or locally hollow, and the body portion has the receiving portion integral with it for inserting into the body portion of the adjacent frame segment. The other branch can have a similar receiving portion and a similar body portion; or simply forms a receiving portion that is extended from the first branch.

If the corner joints are concealed by the frame segments, their two branches can both be a receiving portion adapted for inserting into the body portion of the adjacent frame segment.

In either case, the whole assembled frame will have a smooth outline, forming an appearance that is aesthetically pleasing.

For example, the box body of junction box 50 can be a hollow section bar formed from insulating composite materials (such as by injection molding, extrusion etc.), and is provided with a connecting circuit for gathering and outputting the electrical energy generated by cell panel 10. The connecting circuit can comprise conductive wire 20 which extends and passes through the canister-shaped body portion of the box body of junction 50; bypass diode 52 which is connected in the conductive wire 20 for preventing circuit breaking or reverse current from occurring in the solar cell module; and male connector 22 and female connector 24 which are respectively connected to conductive wire 20 at the opposite sides of diode 52 and respectively have a plug portion and a socket portion, the plug portion and the socket portion respectively protruding, when the frame is assembled, from the vicinity of the opposite ends of junction box 50 or from the two corner joints 34 adjacent to the junction box. Preferably, the plug portion of male connector 22 and the socket portion of female connector 24 are respectively located within frame segments 32b extending along the two long sides of the cell panel, that is, they are concealed and protected by frame segments 32b and are accessible to operators for connection operations. It can be appreciated that the positions of male connector 22 and female connector 24 are interchangeable.

The two bus bars 12 respectively are inserted into the box body of junction box 50 at the two corners on the edge of the cell panel where junction box 50 are located and being connected to conductive wire 20, such that the points of connection of the two bus bars 12 on conductive wire 20 respectively are located at the opposite sides of diode 52. According to this embodiment, the functions of guarding against reverse current and bypassing can be obtained at the same time by disposing two bus bars along the two longitudinally extended edges of the cell panel and connecting them to the connecting circuit disposed along a transversely extended edge of the cell panel.

Junction box 50 can be pre-assembled on cell panel 10, with the electrical connection completed as shown in FIG. 2. Then, junction box 50 and the other frame segments 32a and 32b are assembled by the insertion type corner joints 34 to form the whole frame 30. In this way, the whole thin film solar cell module is assembled, which has a smooth and tidy appearance.

Described hereinafter are thin film solar cell modules according to other preferred embodiments of the present application, wherein the same or similar parts as or to those in the embodiment as shown in FIG. 2 are represented by the same reference signs.

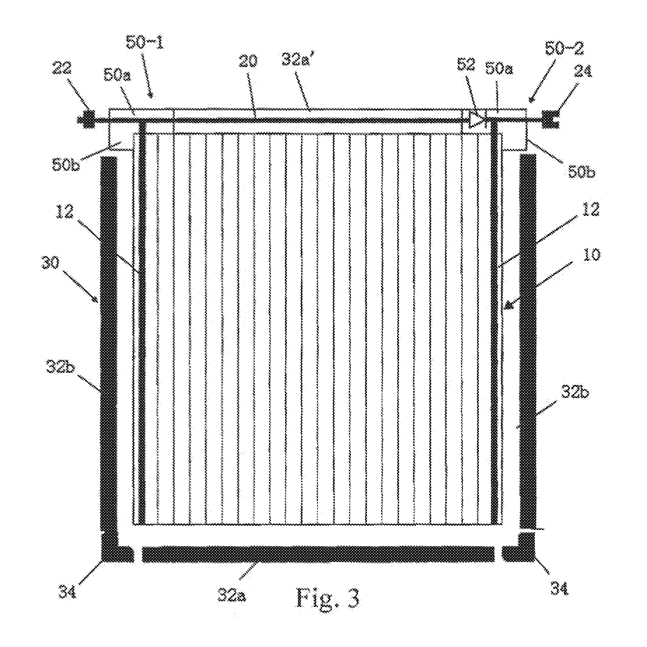

FIG. 3 shows a thin film solar cell module according to another preferred embodiment of the present application. The thin film solar cell module also mainly includes cell panel 10, frame 30 and a junction box.

The substantially rectangular cell panel 10 shown in FIG. 3 comprises a plurality of cells which extend in a longitudinal direction and are connected in series with each other in a transverse direction, and bus bars 12 which respectively extend longitudinally along the left and right edges of the cell panel (the two long sides of the rectangle of the cell panel, as shown in FIG. 3). The electrical current generated by these cells is gathered to bus bars 12.

According to this embodiment, the box body of the junction box is comprised of two portions, that is, corner joint-type box portions 50-1 and 50-2 connected at the opposite ends of frame segment 32a′ extending along a transversely extended edge of cell panel 10 (a short side of the cell panel, as shown in FIG. 3). That is to say, the two corner joint-type box portions 50-1 and 50-2 of the junction box are connected at the opposite ends of frame segment 32a′, forming two corner joints. Moreover, frame 30 also includes the other transversely extended frame segment 32a opposite frame segment 32a′, two longitudinally extended (along the two long sides of the cell panel) frame segments 32b opposite each other, the other two corner joints 34 which, together with the two corner joint-type box portions 50-1 and 50-2 of the junction box, connect these frame segments with each other to form the rectangular frame.

The corner joint-type box portions 50-1 and 50-2 respectively have a transverse branch 50a and a longitudinal branch 50b which are formed integral with each other. Each transverse branch has a receiving portion and a canister-shaped body portion, the receiving portion being adapted for clamping and sealing the edges of the cell panel, and the canister-shaped body portion being used for providing structural strength and rigidity. The canister-shaped body portion of the transverse branch 50a of each of the corner joint-type box portions 50-1 and 50-2 has the receiving portion integral with it for respectively inserting into the hollow body portion of the two adjacent frame segments, thus rapidly assembling the frame segments together. The longitudinal branches can have similar receiving portion and body portion; or simply form a receiving portion that is extended from the transverse branches.

Each of the corner joint-type box portions 50-1 and 50-2 preferably has the same shape as that of the adjacent frame segment.

Frame segment 32a′ combines with transverse branches 50a of the two corner joint-type box portions 50-1 and 50-2 through the receiving portion integral with the body portion of transverse branches 50a, thus forming a smooth outline.

These two corner joint-type box portions 50-1 and 50-2 preferably have an identical or matching shape with that of the other corner joints 34, and all these four corner joints preferably have the same shape as that of the four frame segments. In this way, the whole assembled frame will have a smooth outline, thus forming an aesthetically pleasing appearance.

The box body of the junction box can be formed from insulating composite materials or high strength plastics. The frame segments and the corner joints forming the frame can be respectively made of composite materials, high strength plastics, or metals such as aluminum alloy. The frame segments are preferably obtained by cutting from section bars.

The junction box is provided with a connecting circuit for gathering and outputting the electrical energy generated by cell panel 10. The connecting circuit can comprise conductive wire 20 which extends and passes through transverse branches 50a of the two corner joint-type box portions 50-1 and 50-2 and extends and passes through the canister-shaped body portion of frame segment 32a′; bypass diode 52 which is connected in conductive wire 20 within one of the two corner joint-type box portions 50-1 and 50-2 (within corner joint-type box portion 50-2, as shown in the figure) for preventing circuit breaking or reverse current from occurring in the solar cell module; and male connector 22 and female connector 24 which are respectively connected to conductive wire 20 at the opposite sides of diode 52 and respectively have a plug portion and a socket portion, the plug portion and the socket portion respectively protruding, when the frame is assembled, from the vicinity of the opposite ends of frame segment 32a′ or from the two corner joint-type box portions 50-1 and 50-2. The two bus bars 12 respectively are inserted into corner joint-type box portions 50-1 and 50-2 at the two corners on the edge of the cell panel where the two corner joint-type box portions 50-1 and 50-2 are located and are connected to conductive wire 20, such that the points of connection of the two bus bars 12 on conductive wire 20 respectively are located at the opposite sides of diode 52

According to this embodiment, the functions of guarding against reverse current and bypassing can be obtained at the same time by disposing two bus bars along the two longitudinally extended edges of the cell panel and connecting them to the connecting circuit disposed along a transversely extended edge of the cell panel.

Other aspects of this embodiment are similar to those previously described with reference to FIG. 2.

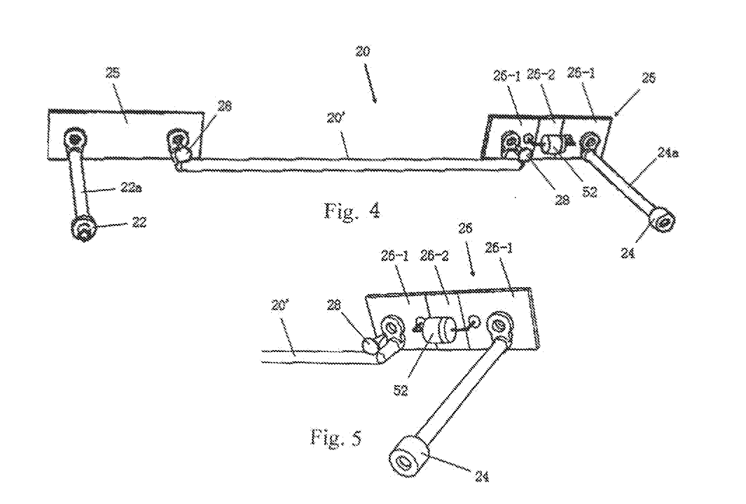

FIGS. 4-11 schematically show the various parts of the thin film solar cell module in FIG. 3 and the mode of assembly.

FIG. 4 shows an exemplary structure of the connecting circuit in the junction box of the thin film solar cell module in FIG. 3. In such a structure, conductive wire 20 includes intermediate wire 20′ which is electrically connected to male connector 22 and female connector 24 through substrates 25 and 26 respectively. Substrate 25 without diode is a conductive plate, such as a copper plate. Substrate 26 with diode 52 is comprised of the internal and external conductive portions 26-1 located on both sides and the insulating portion (such as formed from insulating plastic material) 26-2 located between these two conductive portions for electrically insulating them from each other. The two ends of diode 52 are respectively fastened (such as by welding) to the two conductive portions 26-1. FIG. 5 shows the details of substrate 26 at another angle.

Intermediate wire 20′ can be rigid or flexible, with its both ends being fastened (such as by bolts 28) to substrate 25 and on the inner conductive portion 26-1 of substrate 26 respectively.

One of male connector 22 and female connector 24 (male connector 22 as shown in FIG. 4) is fastened (such as by bolts) to substrate 25 via its lead portion 22a. The other of male connector 22 and female connector 24 (female connector 24 as shown in FIGS. 4 and 5) is fastened (such as by bolts) on the outer conductive portion 26-1 of substrate 26 via its lead portion 24a. In this way, diode 52 is connected in series between male connector 22 and female connector 24. Lead portions 22a and 24a can be rigid or flexible, and they can extend in any direction as desired, not being restricted to extending in the direction as shown in the figures.

The two bus bars are respectively connected to substrate 25 and to outer conductive portion 26-1 of substrate 26, for example, at the connection points same as or different from those of male connector 22 and female connector 24. However, the two bus bars can be connected to other positions of conductive wire 20, so long as the connection points are located on both sides of diode 52.

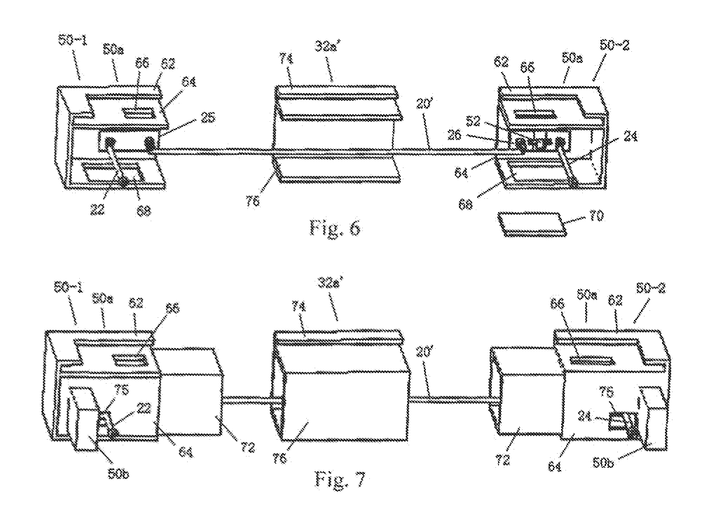

FIGS. 6 and 7 show an exemplary structure for the connection of the connecting circuit with corner joint-type box portions 50-1 and 50-2 and frame segment 32a′. In FIG. 6, corner joint-type box portions 50-1 and 50-2 and frame segment 32a′ are partially cut open to show the connecting circuit portion therein.

It can be seen from FIGS. 6 and 7 that transverse branches 50a of both corner joint-type box portions 50-1 and 50-2 have canister-shaped body portion 64 and receiving portion 62 formed integral above the body portion.

The top wall of body portion 64 is provided with bus bar jack 66 which is used for introducing the corresponding bus bar 12 as shown in FIG. 3. Substrates 25 and 26 are respectively fastened (such as by the bolts as described above for fastening the male and female connectors and the conductive wire to the corresponding substrates) to one of the side walls of body portion 64 of transverse branch 50a of the corresponding corner joint-type box portions 50-1 and 50-2, and the other side wall adjacent to or opposite that side wall is provided with operation orifice 68. The operator can perform operations such as fastening, detection and disassembly on substrates 25 and 26 through the operation orifice. Operation orifice 68 can be sealed by cover plate 70.

It can also be seen from FIGS. 6 and 7 that frame segment 32a′ has canister-shaped body portion 76 and receiving portion 74 formed integral above the body portion. Intermediate wire 20′ extends and passes through body portion 76.

Body portion 76 and receiving portion 74 of frame segment 32a′ preferably have the same shapes as those of body portion 64 and receiving portion 62 of transverse branch 50a.

It can be seen from FIG. 7 that receiving portions 72 are formed at the terminal of body portions 64 of transverse branch 50a of both corner joint-type box portions 50-1 and 50-2 for respectively inserting into canister-shaped body portion 76 of frame segment 32a′.

In the example shown in FIG. 7, longitudinal branches 50b of corner joint-type box portions 50-1 and 50-2 are each in the form of a receiving portion, though longitudinal branches 50b can have a similar construction to that of transverse branch 50a.

When the connecting circuit and corner joint-type box portions 50-1 and 50-2 as shown in FIG. 7 are assembled, the plug portion of male connector 22 and the socket portion of female connector 24 respectively pass through and protrude out of openings 75 in one of the suitable side walls other than the top wall of body portion 64 of transverse branches 50a of both corner joint-type box portions 50-1 and 50-2.

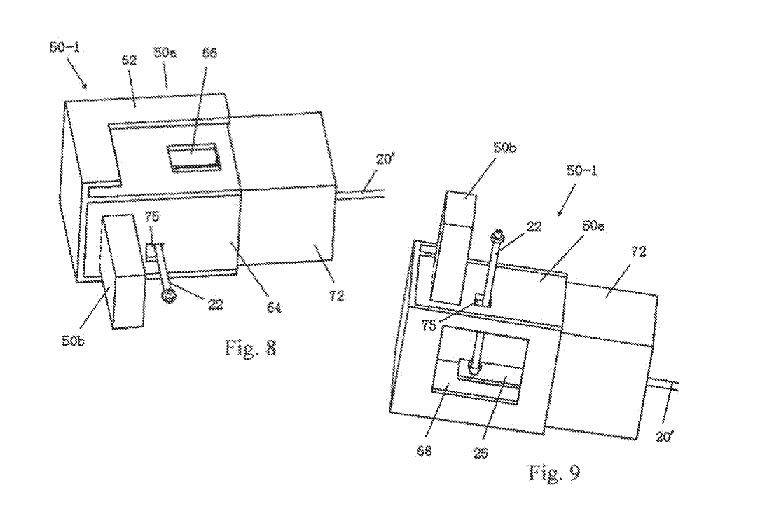

FIGS. 8 and 9 show the enlarged corner joint-type box portion 50-1 in different angles.

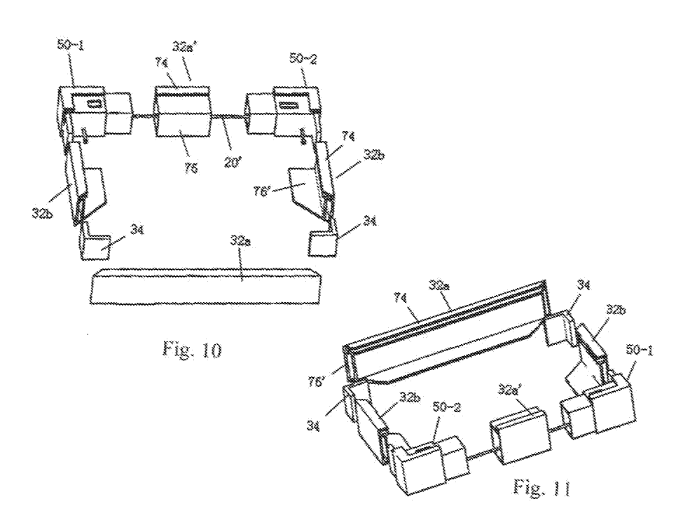

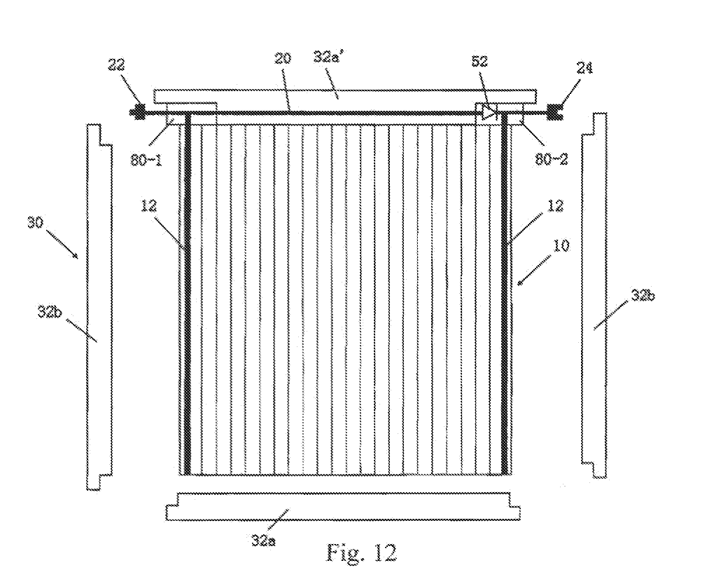

FIGS. 10 and 11 show, in different angles, the assembling relationship of the various parts of frame 30 shown in FIG. 3. The male connector and the female connector extend into frame segments 32b extending along the two long sides of the cell panel, that is, they are concealed and protected by frame segments 32b and are accessible to operators for connection operations.

Moreover, in FIGS. 10 and 11, frame segments 32a and 32b are shown to have the same receiving portion 74 as frame segment 32a′, but body portion 76′ of frame segments 32a and 32b has an open type cross section, which is different from canister-shaped body portion 76 of frame segment 32a′. Body portion 76′ of frame segments 32a and 32b can have various other appropriate cross sections, for example, the same cross section as that of canister-shaped body portion 76 of frame segment 32a′.

Additionally, in FIGS. 10 and 11, corner joints 34 are each shown to be comprised of two receiving portions formed integral with each other which are used for inserting into adjacent frame segments, the corner joints thus being concealed by the frame segments and becoming invisible. However, corner joints 34 can also each be constructed to have the same shape as that of corner joint-type box portions 50-1 and 50-2, the corner joints thus being visible after being assembled with the adjacent frame segments. Further, frame segments 32a and 32b are shown to have receiving portions with an identical or matching shape with that of corner joint-type box portions 50-1 and 50-2, but have body portions with different shapes from each other. However, the frame segments can also have the body portion with the same shape as that of corner joint-type box portions 50-1 and 50-2.

No matter what forms corner joints 34 may take, and no matter whether the shape of frame segments 32a and 32b is identical with that of corner joint-type box portions 50-1 and 50-2, it can be ensured that the whole assembled frame will have a smooth outline, thus forming an aesthetically pleasing appearance.

FIG. 12 shows a thin film solar cell module according to another preferred embodiment of the present disclosure, which is a modification to the scheme as shown in FIG. 3 where the two corner joints connected at the opposite sides of frame segment 32a′ are formed by the junction box.

As shown in FIG. 12, according to this embodiment, the box body of the junction box is comprised of two portions 80-1 and 80-2, which are disposed at the opposite ends of frame segment 32a′ extending along a transversely extended edge of cell panel 10 (a short side of the cell panel as shown in FIG. 12).

Moreover, frame 30 also includes the other transversely extended frame segment 32a opposite frame segment 32a′, and two longitudinally extended (along the two long sides of the cell panel) frame segments 32b opposite each other. These frame segments are all formed by cutting from section bars made of appropriate composite materials, high strength plastics, or metals such as aluminum alloy, and some or all of them have assembling notches which are made at the joining ends. These four frame segments are assembled with each other directly, without the need to use corner joints.

Likewise, in this embodiment, the functions of guarding against reverse current and bypassing can be obtained at the same time by disposing two bus bars along the two longitudinally extended edges of the cell panel and connecting them to the connecting circuit disposed along a transversely extended edge of the cell panel. Other aspects of this embodiment are similar to those previously described with reference to FIG. 3.

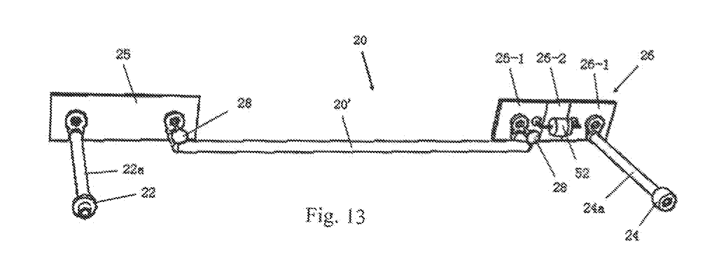

FIG. 13-20 schematically shows the various parts of the thin film solar cell module in FIG. 12 and their mode of assembling.

FIG. 13 shows an exemplary structure of the connecting circuit in the junction box of the thin film solar cell module in FIG. 12. In such a structure, conductive wire 20 includes intermediate wire 20′ which is electrically connected to male connector 22 and female connector 24 through substrates 25 and 26 respectively. Substrate 25 without diode 52 is a conductive plate, such as a copper plate. Substrate 26 with diode 52 is comprised of the internal and external conductive portions 26-1 located on both sides and the insulating portion (such as formed from insulating plastic material) 26-2 located between these two conductive portions for electrically insulating them from each other. The two ends of diode 52 are respectively fastened (such as by welding) to the two conductive portions 26-1.

Intermediate wire 20′ can be rigid or flexible, with its both ends being fastened (such as by bolts 28) to substrate 25 and to the inner conductive portion 26-1 of substrate 26 respectively. One of male connector 22 and female connector 24 (male connector 22 as shown in FIG. 13) is fastened (such as by bolts) to substrate 25 via its lead portion 22a. The other of male connector 22 and female connector 24 (female connector 24 as shown in FIG. 13) is fastened (such as by bolts) to the outer conductive portion 26-1 of substrate 26 via its lead portion 24a. In this way, diode 52 is connected in series between male connector 22 and female connector 24. Lead portions 22a and 24a can be rigid or flexible, and they can extend in any direction as desired, not being restricted to extending in the direction as shown in the figures.

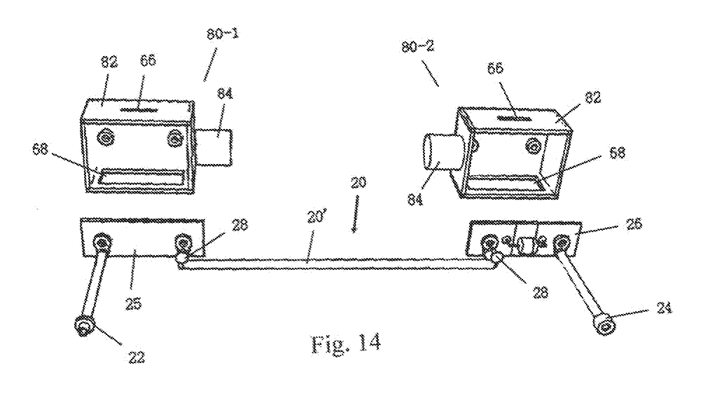

FIG. 14 shows an exemplary structure for the connection of the connecting circuit with box portions 80-1 and 80-2. It can be seen in FIG. 14 that box portions 80-1 and 80-2 respectively include case-shaped body 82 having a front opening and orientation tube portion 84 protruding transversely from the case-shaped body. The top wall of case-shaped body 82 is provided with bus bar jack 66 which is used for introducing the corresponding bus bar 12 as shown in FIG. 12. Substrates 25 and 26 are respectively fastened (such as by the bolts as described above for fastening the male and female connectors and the conductive wire to the corresponding substrates) to one of the side walls of case-shaped body 82 of the corresponding box portions 80-1 and 80-2, and intermediate wire 20′ passes through orientation tube portion 84 and is directed by it. Orientation tube portion 84 is also used for inserting into frame segment 32a′ to facilitate positioning the box portion relative to frame segment 32a′.

The other side wall adjacent to or opposite that side wall is provided with operation orifice 68, through which the operator can perform operations such as fastening, detection and disassembly on substrates 25 and 26. Operation orifice 68 can be sealed by a cover plate which is not shown (similar to cover plate 70 as shown in FIG. 6).

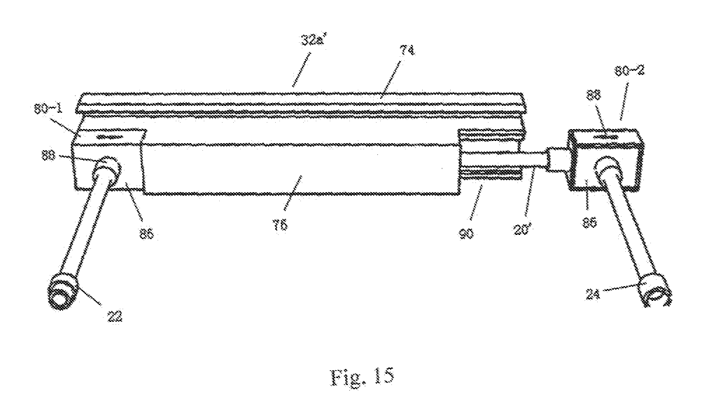

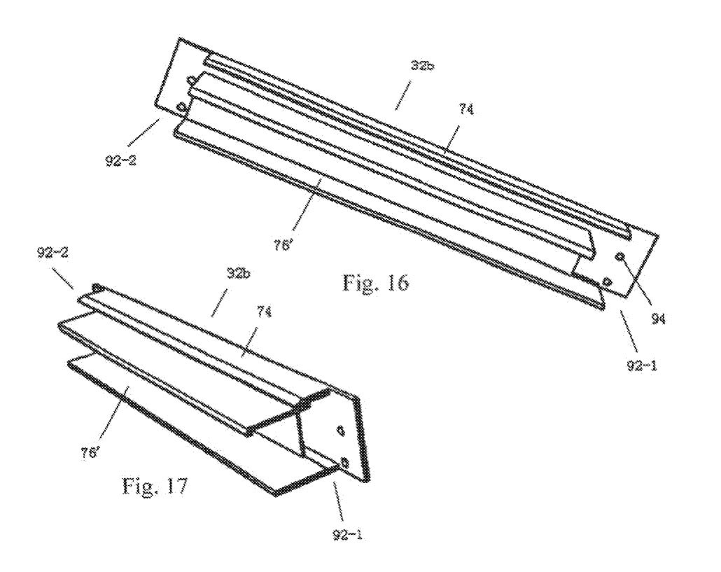

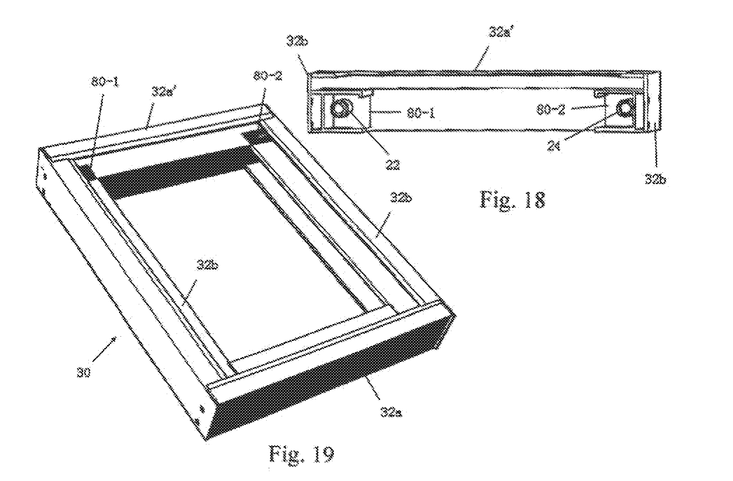

Referring to FIG. 15, the front opening of case-shaped body 82 is also sealed by corresponding wall plate 86, with the lead portions of male connector 22 and female connector 24 respectively passing through corresponding wall plate 86. Wall plate 86 is provided with orientation tube portion 88 for directing the lead portion of male connector 22 and female connector 24.

From FIG. 15 it can also be seen that frame segment 32a′ formed from a section bar segment has canister-shaped body portion 76 and receiving portion 74 formed integral above the body portion. Intermediate wire 20′ extends and passes through body portion 76.

From FIG. 15 it can be seen that accommodation notches 90 suitable for accommodating box portions 80-1 and 80-2 are cut at the lower part of canister-shaped body portion 76 on both ends of frame segment 32a′. In FIG. 15, box portion 80-1 has been assembled in the accommodation notch on the left end of canister-shaped body portion 76, while box portion 80-2 is to be assembled in the accommodation notch on the right end of canister-shaped body portion 76.

FIGS. 16 and 17 show, in different angles, one of frame segments 32b extending along the two long sides of the cell panel. Each of frame segments 32b has open type body portion 76′ and receiving portion 74 formed integral above the body portion, and frame segment 32a can have identical open type body portion and receiving portion. It can be appreciated, of course, that frame segments 32a and 32b can have the same canister-shaped body portion as that of frame segment 32a′, or can have a body portion with any of various other appropriate cross sections.

Moreover, on both ends of frame segment 32b, the body portion and the receiving portion are cut to form assembling notches, with assembling notch 92-1 being adjacent to box portion 80-1 or 80-2 of frame segment 32a′, and assembling notch 92-2 being adjacent to frame segment 32a. The part of the body portion for assembling notch 92-1 is cut slightly larger to provide an accommodation space for the body portion of frame segment 32a′ and the corresponding box portion.

Additionally, on both ends of frame segment 32b, orifices 94 adapted for being passed through by bolts are provided on receiving portion 74 and used for assembling frame segment 32a′ and frame segment 32a to frame segment 32b.

For the frame segments 32a and 32b like that shown in FIGS. 16 and 17, no assembling notches are made at the terminal parts of the matching frame segment 32a′ and frame segment 32a. Of course, if necessary, assembling notches can be made at the terminal parts of frame segment 32a′ and frame segment 32a.

FIG. 18 shows the state after frame segments 32a and 32b are assembled to frame segment 32a′ with box portions 80-1 and 80-2, wherein the plug portion of male connector 22 and the socket portion of female connector 24 extend into the open type body portions of frame segments 32b, that is, they are concealed and protected by frame segments 32b and are accessible to operators for connection operations.

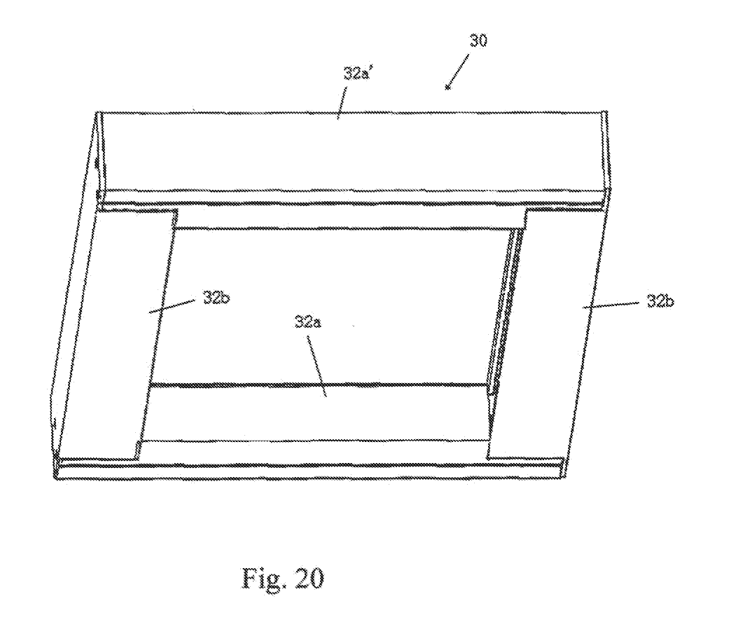

FIGS. 19 and 20 show the completely assembled frame 30 from top view and bottom view respectively. As shown in FIG. 19, in the assembled frame 30, box portions 80-1 and 80-2 are visible from the front side of the frame. As shown in FIG. 20, box portions 80-1 and 80-2 are invisible from the back side of the frame. However, whether seen from the front side or the back side, the frame 30 has a smooth and aesthetically pleasing appearance.

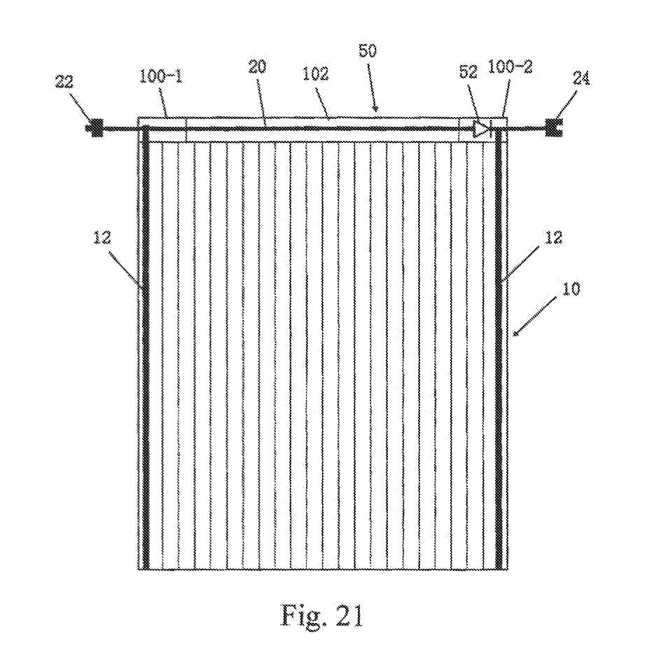

FIG. 21 shows a thin film solar cell module according to another preferred embodiment of the present disclosure, which is frameless and suitable for use e.g., in a double-glass module (that is, the cell panel has a front panel and a substrate both made of glass, or has a superstrate and a back plate both made of glass).

As shown in FIG. 21, according to this embodiment, the thin film solar cell module mainly includes cell panel 10 and junction box 50. Cell panel 10 comprises a plurality of cells which extend in a longitudinal direction (in the direction parallel to the long sides of the rectangle of the cell panel, as shown in the figure) and are connected in series with each other in a transverse direction, and bus bars 12 which respectively extend longitudinally along the left and right edges of the cell panel (the two long sides of the rectangle of the cell panel, as shown in FIG. 21). The electrical current generated by these cells is gathered to junction box 50 via bus bars 12.

Junction box 50 extends along a transversely extended edge of cell panel 10 (a short side of the cell panel, as shown in FIG. 21). The box body of junction box 50 is comprised of three portions, that is, box portions 100-1 and 100-2 located on both ends of the transversely extended edge of cell panel 10 and intermediate segment 102 connected between these two box portions. These two box portions and the intermediate segment have identical shape, such as rectangular shape, such that junction box 50 thus formed has a smooth outline.

Junction box 50 is provided with a connecting circuit for gathering and outputting the electrical energy generated by cell panel 10. The connecting circuit can comprise conductive wire 20 which extends and passes through the two box portions 100-1 and 100-2 and intermediate segment 102; bypass diode 52 which is connected in the conductive wire 20 within one of the two box portions 100-1 and 100-2 (in box portion 100-2 as shown in the FIG. 21) for preventing circuit breaking or reverse current from occurring in the solar cell module; and male connector 22 and female connector 24 which are respectively connected to conductive wire 20 at the opposite sides of diode 52, with their plug portion or socket portion protruding, when the frame is assembled, from the respective end of junction box 50. The two bus bars 12 respectively are inserted into box portions 100-1 and 100-2 at the two corners on the edge of the cell panel where junction box 50 is located and are connected to conductive wire 20, such that the points of connection of the two bus bars 12 on conductive wire 20 respectively are located at the opposite sides of diode 52

According to this embodiment, the functions of guarding against reverse current and bypassing can be obtained at the same time by disposing two bus bars along the two longitudinally extended edges of the cell panel and connecting them to the connecting circuit disposed along a transversely extended edge of the cell panel.

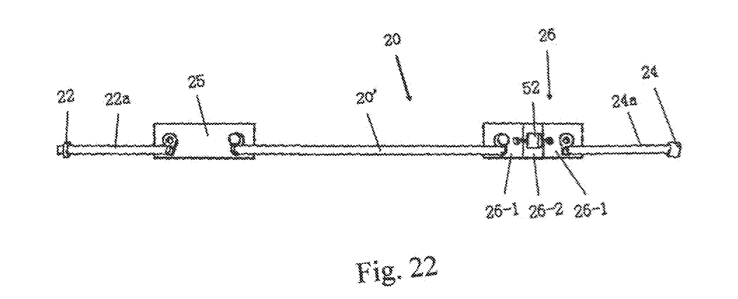

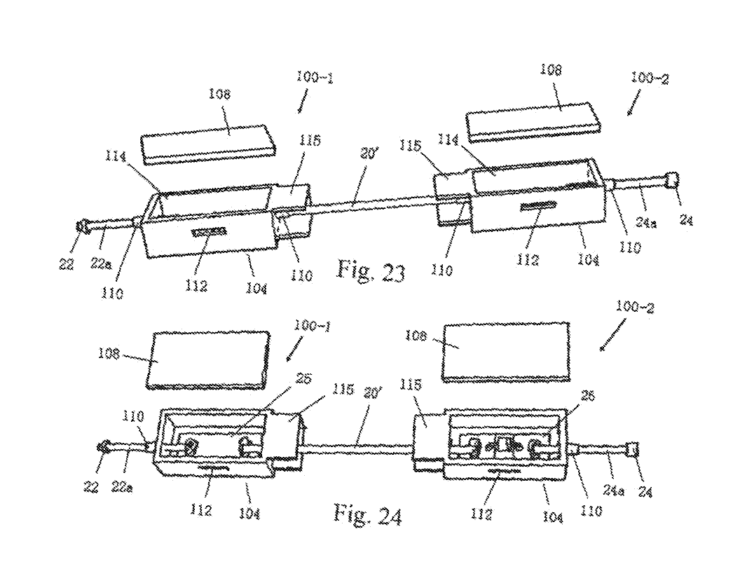

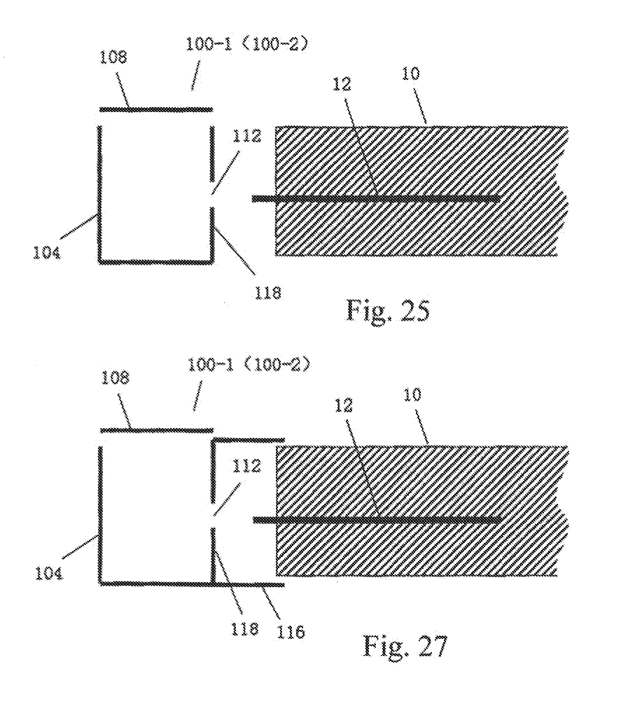

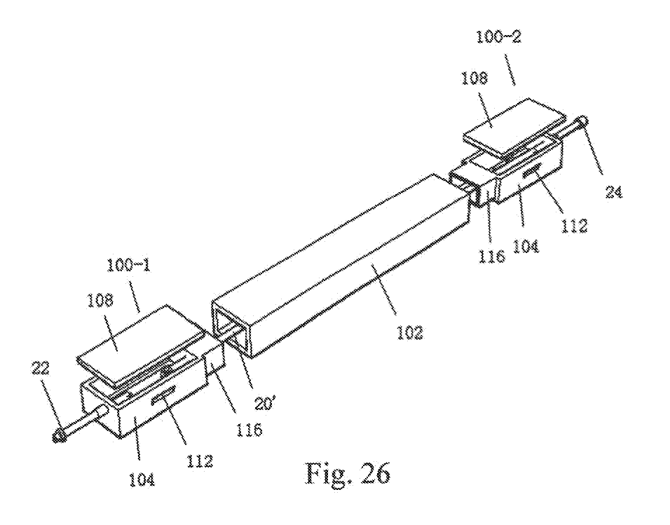

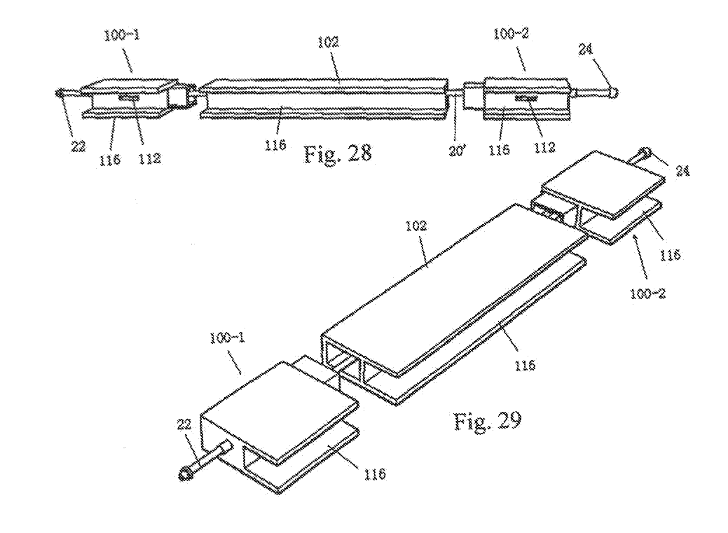

FIG. 22-29 schematically shows the various parts of the thin film solar cell module in FIG. 21 and the mode of assembly.

FIG. 22 shows an exemplary structure of the connecting circuit in the junction box of the thin film solar cell module in FIG. 21. In such a structure, intermediate wire 20′ of conductive wire 20 is electrically connected to male connector 22 and female connector 24 through substrate 25 without diode 52 and substrate 26 with diode 52. Substrate 25 is a conductive plate, such as a copper plate. Substrate 26 is comprised of the internal and external conductive portions 26-1 located on both sides and the insulating portion (such as formed from insulating plastic material) 26-2 located between these two conductive portions for electrically insulating them from each other. The two ends of diode 52 are respectively fastened (such as by welding) to the two conductive portions 26-1. Male connector 22 is fastened to substrate 25 via its lead portion 22a, and female connector 24 is fastened to the external conductive portion 26-1 of substrate 26 via its lead portion 24a. In this way, diode 52 is connected in series between male connector 22 and female connector 24. Lead portions 22a and 24a can be rigid or flexible, and they can extend in any direction as desired, not being restricted to extending in the direction as shown in the figures.

FIGS. 23 and 24 show, from different angles, an exemplary structure for the connection of the connecting circuit with box portions 100-1 and 100-2. From FIGS. 23 and 24 it can be seen that box portions 100-1 and 100-2 respectively include case-shaped body 104. Each case-shaped body 104 has top operation orifice 114 which is sealed by corresponding wall plate 108.

Each case-shaped body 104 also has orientation tube portions 110 which protrude from its two transverse ends. Intermediate wire 20′ and lead portions 22a and 24a of the male and female connectors respectively pass through and are directed by corresponding orientation tube portions 110.

Each case-shaped body 104 further has receiving portion 115 which protrudes from its transverse internal end and which is used for inserting into intermediate segment 102 to facilitate positioning box portions 100-1 and 100-2 relative to intermediate segment 102.

The side wall of each case-shaped body 104 facing cell panel 10 is provided with bus bar jack 112 for introducing corresponding bus bars 12 as shown in FIGS. 25 and 26.

Substrates 25 and 26 are respectively fastened to one of the side walls of case-shaped body 104 of box portions 100-1 and 100-2.

FIG. 25 schematically shows an exemplary mode of connection between box portions 100-1 and 100-2 and cell panel 10, in which the side wall of case-shaped body 104 of box portions 100-1 or 100-2 facing cell panel 10 is coated with an adhesive such as silica gel on its outer surface 118. The ends of bus bars 12 of cell panel 10 are inserted into box portions 100-1 or 100-2 through bus bar jacks 112 in the box portions. Then case-shaped body 104 of box portions 100-1 or 100-2 is pushed against the edge of cell panel 10 such that the box portions and the cell panel are connected together via the adhesive. It can be appreciated that, in this embodiment, the intermediate segment is connected to the cell panel in a way similar to that of the box portions. FIG. 26 shows the assembling relationship between box portions 100-1 and 100-2 and the corresponding intermediate segment 102 in FIG. 25.

FIG. 27 shows another exemplary mode of connection between box portions 100-1 or 100-2 and cell panel 10, which is different from that as shown in FIG. 25 in that receiving portion 116 extending towards the cell panel is provided on case-shaped body 104 of box portions 100-1 or 100-2. The box portions are connected to cell panel 10 by inserting the edge of the cell panel into receiving portion 116 and adhering them using an adhesive such as silica gel coated on outer surface 118. It can be appreciated that, in this embodiment, the intermediate segment also has a similar receiving portion and is connected to the cell panel in a similar way to that of the box portions. FIGS. 28 and 29 show the assembling relationship between box portions 100-1 and 100-2 and the corresponding intermediate segment 102 in FIG. 27, with receiving portion 116 visible on intermediate segment 102.

It should be pointed out that hereinabove described are various embodiments of the present application. It can be appreciated that some features in a certain embodiment can be likewise applied to other embodiments.

It should also be pointed out that while the description is made herein by reference to a rectangular cell panel, the basic concept of the present application is likewise applicable to thin film solar cell panels with other shapes. No matter what form the cell panel may take, according to the basic concept of the present application, it is always the case that two bus bars can be disposed along the two longitudinally extended edges of the cell panel and be connected to the connecting circuit disposed along a transversely extended edge of the cell panel so as to obtain at the same time the functions of guarding against reverse current and bypassing.

It should also be pointed out that the basic concept of the present application is applicable to both the thin film solar cell modules with a frame and the thin film solar cell modules without a frame.

In the case of the thin film solar cell modules with a frame, the forms and specific constructions of the frame are not limited to those shown and described herein. For example, the frame can have an upper and a lower layer, that is, it is double-layered, with each layer being an integral molded frame portion. A complete frame is formed simply by clasping the two layers of frame portions around the edges of the cell panel or connecting them in other ways. Other forms of the frame are likewise suitable for use in the thin film solar cell modules of the present application.

Also, according to the present application, the junction box of the thin film solar cell modules is disposed along a transversely extended edge of the cell panel instead of being directly disposed beneath the solar cells at the back side of the cell panel. Therefore, there is no need to cut or bore in the back panel, and the junction box will not bring about localized temperature rise in the assembly which would otherwise affect the efficiency of the assembly and reduce the long-term service lifetime of the assembly.

Also, the thin film solar cell modules according to the present application can be easily assembled through only simple operations.

Also, during the assembling of the solar cell system comprised of a plurality of thin film solar cell modules, the connection of these modules can be achieved through the simple insertion and joining of their male and female connectors, without the need to use any additional cables.

This allows that the assembling process can be achieved in a simple, fast and low-cost way. Moreover, the detection and maintenance of the thin film solar cell modules can easily be performed.

Additionally, there is no junction box and outputting wire on the back side of the thin film solar cell modules according to the present application, therefore the back side of the cell module is plain and pleasing to the eye.

While the presently disclosed invention has be illustrated and described with reference to preferred embodiments thereof, it will be appreciated by those skilled in the art that various changes and modifications can be made without departing from the scope of the present invention as defined in the appended claims.

What is claimed is:

1. A thin film solar cell module, comprising:
a thin film solar cell panel comprising a layer of solar cells and a plurality of bus bars, the layer of solar cells including a plurality of solar cells which extend in a longitudinal direction and are connected in series with each other in a transverse direction, and the bus bars respectively extending along two longitudinally extended edges of the solar cell panel for outputting electrical energy generated by the solar cells; and
a junction box disposed along a transversely extended edge of the solar cell panel and comprising a box body and a connecting circuit for gathering and outputting electrical energy generated by the solar cell panel, the connecting circuit extending along the whole length of said transversely extended edge of the solar cell panel, and comprising a conductive wire at least a part thereof passing through the box body of the junction box, a bypass diode connected in the connecting circuit within the box body of the junction box for preventing circuit breaking or reverse current from occurring in the solar cell panel, with the two bus bars connected to the connecting circuit at the opposite sides of the bypass diode respectively; and a male and a female connector connected to the connecting circuit at the opposite sides of the bypass diode respectively for providing external connections;
wherein the two bus bars are directly connected to the connecting circuit at the opposite ends of said transversely extended edge of the solar cell panel.

2. The thin film solar cell module according to claim 1, wherein the box body of the junction box forms a frame segment extending along said transversely extended edge of the solar cell panel;
the thin film solar cell module further comprises additional frame segments; and
the frame segment extending along said transversely extended edge of the cell panel and the additional frame segments form a frame that at least partially surrounds the periphery of the solar cell panel.

3. The thin film solar cell module according to claim 2, wherein the frame segment formed by the box body of the junction box is made of an insulating material.

4. The thin film solar cell module according to claim 3, wherein the additional frame segments are made of a composite material or a metal.

5. The thin film solar cell module according to claim 2, wherein the additional frame segments are section bar segments cut from a section bar.

6. The thin film solar cell module according to claim 2, wherein a plug portion of the male connector and a socket portion of the female connector extend out from the frame segment extending along said transversely extended edge of the solar cell panel at both ends of the frame segment.

7. The thin film solar cell module according to claim 2, wherein the additional frame segments comprise a body portion and a receiving portion formed integral with the body portion adapted for clamping an edge of the solar cell panel.

8. The thin film solar cell module according to claim 7, wherein the frame segment formed by the box body of the junction box comprises a canister-shaped body portion and a receiving portion formed integral with the body portion adapted for clamping an edge of the solar cell panel; and
wherein the receiving portion of the frame segment formed by the box body of the junction box has an external shape identical with that of the receiving portion of the additional frame segments.

9. The thin film solar cell module according to claim 1, wherein the box body of the junction box comprises two box portions which are respectively disposed at the opposite ends of said transversely extended edge of the solar cell panel; the connecting circuit comprises two substrates respectively disposed in the two box portions and an intermediate wire connected between the two substrates, with the bypass diode being disposed on one of the substrates; the substrate with the bypass diode being comprised of an inner conductive portion, an outer conductive portion and an insulating portion positioned between and electrically isolating the inner and the outer conductive portions, with the ends of the bypass diode being fastened to the inner and outer conductive portions respectively, and the other substrate without the bypass diode is a conductive plate; one of the male and female connectors is connected to the conductive plate, and the other of the male and female connectors is connected to the outer conductive portion of the substrate with the bypass diode.

10. The thin film solar cell module according to claim 9, wherein the two box portions form corner joints at the opposite ends of the same frame segment which extends along said transversely extended edge of the solar cell panel.

11. The thin film solar cell module according to claim 9, wherein the two box portions are assembled at the opposite ends of the same frame segment which extends along said transversely extended edge of the solar cell panel.

12. The thin film solar cell module according to claim 1, wherein the thin film solar cell module is frameless.

13. The thin film solar cell module according to claim 12, wherein the thin film solar cell panel is of the type with dual glass panels.

14. The thin film solar cell module according to claim 13, wherein the box body of the junction box comprises two box portions which are disposed at the opposite ends of said transversely extended edge of the solar cell panel; the connecting circuit comprises two substrates respectively disposed in the two box portions and an intermediate wire connected between the two substrates, with the bypass diode being disposed on one of the substrates; the substrate with the bypass diode being comprised of an inner conductive portion, an outer conductive portion and an insulating portion positioned between and electrically isolating the inner and the outer conductive portions, with the ends of the bypass being fastened to the inner and outer conductive portions respectively, and the other substrate without the bypass diode is a conductive plate; one of the male and female connectors is connected to the conductive plate, and the other of the male and female connectors is connected to the outer conductive portion of the substrate with the bypass diode.

15. The thin film solar cell module according to claim 14, wherein the box body of the junction box further comprises an intermediate segment disposed between the two box portions, with the two box portions and the intermediate segment having the same external shape.

16. The thin film solar cell module according to claim 15, wherein the box body of the junction box is adhesively attached to said transversely extended edge of the solar cell panel.

17. The thin film solar cell module according to claim 16, wherein the two box portions and the intermediate segment of the box body of the junction box are each provided with a receiving portion for receiving an edge of the solar cell panel.
